(19) United States
(12) Patent Application Publication
(10) Pub. No.: US 2017/0297311 A1
(43) Pub. Date: Oct. 19, 2017

(54) CONDUCTIVE SHEET

(71) Applicant: NITTO DENKO CORPORATION, Ibaraki-shi, Osaka (JP)

(72) Inventors: Shoichi Matsuda, Ibaraki-shi (JP); Hiroshi Tomohisa, Ibaraki-shi (JP); Kazumasa Okada, Ibaraki-shi (JP)

(73) Assignee: NITTO DENKO CORPORATION, Ibaraki-shi, Osaka (JP)

(21) Appl. No.: 15/512,976

(22) PCT Filed: Sep. 14, 2015
(86) PCT No.: PCT/JP2015/075975

§ 371 Date: Mar. 21, 2017

(30) Foreign Application Priority Data
Sep. 22, 2014 (JP) 2014-192645
Sep. 11, 2015 (JP) 2015-179293

(51) Int. Cl. B32B 27/06; B32B 5/02; H05K 9/00; H01B 5/14; G02B 5/30; G02F 1/1335; G02F 1/1333

(52) U.S. Cl. CPC B32B 27/06; H01B 5/14; B32B 5/028; H05K 9/0081; G02B 5/3016; B32B 2307/42; B32B 2307/412; B32B 2307/202; G02F 1/133308; G02F 1/133528; G02F 2001/133334; G02F 2001/133507; G02F 1/133504

(57) ABSTRACT

Provided is a conductive sheet including a transparent conductive layer and a brightness enhancement film, in which interlayer peeling hardly occurs. A conductive sheet of the present invention includes a brightness enhancement film, a resin layer, and a transparent conductive layer in the stated order. In one embodiment, the transparent conductive layer contains metal nanowires. In one embodiment, the metal nanowires include silver nanowires. In one embodiment, the transparent conductive layer further contains a binder resin.

### TECHNICAL FIELD

The present invention relates to a conductive sheet.

### BACKGROUND ART

In recent years, the construct ion of a display apparatus has become more and more complicated. A plurality of electronic instruments are often mounted thereon, and an unnecessary electromagnetic noise occurs between the respective electronic instruments. A conductive sheet that expresses an electromagnetic shielding characteristic has been used for suppressing an influence of such electromagnetic noise. In, for example, Patent Literature 1, there is a disclosure of a liquid crystal display apparatus in which a shield electrode is arranged on the side of an insulating substrate where a liquid crystal layer is formed. In such construction, a pixel electrode or a common electrode is arranged at a position close to the shield electrode, and hence the structure of the apparatus becomes extremely complicated.

One possible means for suppressing an influence of an electromagnetic noise between electronic instruments in a display apparatus, such as a liquid crystal display apparatus, without making its structure complicated is the formation of a transparent conductive layer on a brightness enhancement film to be included in the display apparatus. However, the transparent conductive layer formed on the brightness enhancement film involves a problem in that its adhesiveness with the brightness enhancement film is insufficient and hence interlayer peeling is liable to occur.

### CITATION LIST

### Patent Literature

[PTL 1] JP 2013-015766 A

### SUMMARY OF INVENTION

### Technical Problem

The present invention has been made to solve the problem, and an object of the present invention is to provide a conductive sheet including a transparent conductive layer and a brightness enhancement film, in which interlayer peeling hardly occurs.

### Solution to Problem

According to one embodiment of the present invention, there is provided a conductive sheet, including a brightness enhancement film, a resin layer, and a transparent conductive layer in the stated order.

In one embodiment, the transparent conductive layer contains metal nanowires.

In one embodiment, the metal nanowires include silver nanowires.

In one embodiment, the transparent conductive layer further contains a binder resin.

In one embodiment, the transparent conductive layer contains a metal mesh.

In one embodiment, the transparent conductive layer contains a conductive polymer.

In one embodiment, the brightness enhancement film includes a linearly polarized light separation-type brightness enhancement film.

In one embodiment, the brightness enhancement film includes a circularly polarized light separation-type brightness enhancement film.

In one embodiment, the resin layer contains an acrylic curable resin.

In one embodiment, the resin layer is directly formed on the brightness enhancement film, and the transparent conductive layer is directly formed on the resin layer.

In one embodiment, the conductive sheet of the present invention has a single axis transmittance of from 30% to 70%.

In one embodiment, a surface of the conductive sheet of the present invention on a transparent conductive layer side has a surface resistance value of from 10⁻² Ω/□ to 10⁴ Ω/□.

According to another embodiment of the present invention, there is provided an optical laminate. The optical laminate includes the conductive sheet and a polarizing plate.

In one embodiment, the polarizing plate is arranged on a brightness enhancement film side of the conductive sheet.

In one embodiment, a polarized light transmission axis of the conductive sheet and a polarized light transmission axis of the polarizing plate are parallel to each other.

### Advantageous Effects of Invention

According to the present invention, the conductive sheet in which interlayer peeling hardly occurs can be obtained by laminating the brightness enhancement film and the transparent conductive layer through intermediation of the resin layer.

### BRIEF DESCRIPTION OF DRAWINGS

FIG. 1 is a schematic sectional view of a conductive sheet according to one embodiment of the present invention.

FIG. 2 is a schematic sectional view of an optical laminate according to one embodiment of the present invention.

### DESCRIPTION OF EMBODIMENTS

A. Entire Construction of Conductive Sheet

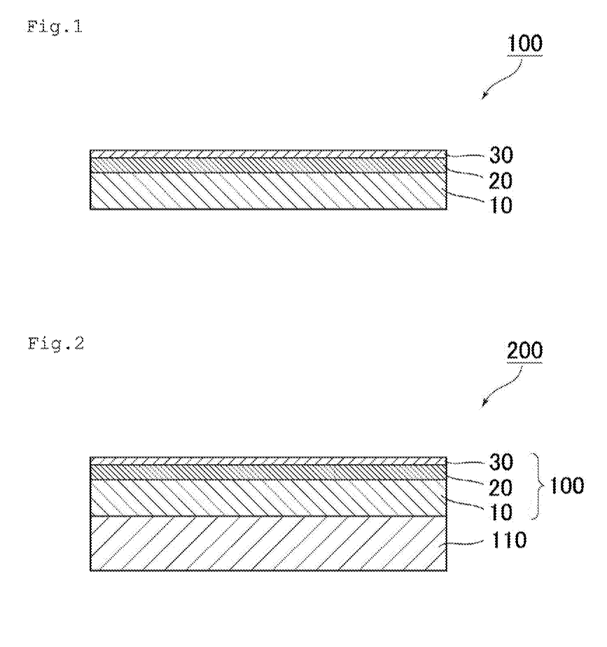

FIG. 1 is a schematic sectional view of a conductive sheet according to one embodiment of the present invention. A conductive sheet 100 illustrated in FIG. 1 includes a brightness enhancement film 10, a resin layer 20, and a transparent conductive layer 30 in the stated order.

It is preferred that the resin layer 20 be directly formed on the brightness enhancement film 10. In addition, it is preferred that the transparent conductive layer 30 be directly formed on the resin layer 20.

In general, the brightness enhancement film is a dynamically brittle film because the film includes a stretched film or includes a liquid crystal layer. Accordingly, when the transparent conductive layer is directly formed on the surface of the brightness enhancement film, interfacial failure occurs and hence the transparent conductive layer is liable to peel. In the present invention, the brightness enhancement film and the transparent conductive layer are laminated through intermediation of the resin layer, and hence the resin layer functions as a stress relaxation layer. As a result, a conductive sheet in which interlayer peeling hardly occurs can be obtained. The resin layer is preferably a resin layer including a curable resin excellent in affinity for the brightness enhancement film, and for example, an acrylic curable resin may be used. Details about the resin layer are described later.

The transmittance of the conductive sheet of the present, invention is preferably from 30% to 70%, more preferably from 40% to 70%. The conductive sheet of the present invention includes the brightness enhancement film, and the brightness enhancement film has a characteristic of transmitting polarized light as described later. Accordingly, the transmittance of the conductive sheet means a single axis transmittance. A method of measuring the single axis transmittance is described later.

The polarization degree of the conductive sheet of the present invention is preferably 80% or more, more preferably 90% or more.

The surface resistance value of the surface of the conductive sheet of the present invention on a transparent conductive layer side is preferably from 10⁻² Ω/□ to 10⁴ Ω/□, more preferably from 10⁻² Ω/□ to 10³ Ω/□. When the surface resistance value falls within such range, a conductive sheet useful as an electromagnetic shield can be obtained.

B. Brightness Enhancement Film

The brightness enhancement film is a film configured to enhance brightness through the separation of polarized light, and may be of a linearly polarized light separation type or maybe of a circularly polarized light separation type. Examples of the brightness enhancement film include a film including a stretched film and a film including a liquid crystal layer. The brightness enhancement film has the following function: when natural light (e.g., light from the backlight of an image display apparatus) enters the film, the film separates the light into two polarized light components, transmits linearly polarized light having a predetermined polarization axis or circularly polarized light having a predetermined direction, and reflects the untransmitted polarized light. When depolarized light obtained by passing the untransmitted polarized light through a reflective plate or the like is caused to reenter the brightness enhancement film, the utilization efficiency of predetermined polarized light can be improved.

B-1. Linearly Polarized Light Separation-type Brightness Enhancement Film

A linearly polarized light separation-type brightness enhancement film has the following function: the film separates incident light into two polarized light components perpendicular to each other, transmits one polarized light component, and reflects the other polarized light component. The linearly polarized light separation-type brightness enhancement film is preferably a laminate including a thermoplastic resin layer (A) and a thermoplastic resin layer (B). The linearly polarized light separation-type brightness enhancement film is typically a film in which the thermoplastic resin layer (A) and the thermoplastic resin layer (B) are alternately arranged (ABABAB . . . ). The number of layers constituting the linearly polarized light separation-type brightness enhancement film is preferably from 2 to 50, more preferably from 2 to 30. The linearly polarized light separation-type brightness enhancement film having such structure is produced by, for example, co-extruding two kinds of resins and stretching the extruded film. The total thickness of the linearly polarized light separation-type brightness enhancement film is preferably from 15 μm to 800 μm.

The thermoplastic resin layer (A) preferably shows optical anisotropy. The in-plane birefringent index (ΔnA) of the thermoplastic resin layer (A) is preferably 0.05 or more, more preferably 0.1 or more, particularly preferably 0.15 or more. An upper limit, value for the ΔnA is preferably 0.4 from the viewpoint of optical uniformity. Here, the ΔnA represents a difference (nxA-nyA) between nxA (refractive index in a slow axis direction) and nyA (refractive index in a fast axis direction).

It is preferred that the thermoplastic resin layer (B) substantially show optical isotropy. The in-plane birefringent index (ΔnB) of the thermoplastic resin layer (B) is preferably 5×10⁻² or less, more preferably 1×10⁻² or less, particularly preferably 0.5×10⁻² or less. A lower limit value for the ΔnB is preferably 0.01×10⁻⁶. Here, the ΔnB represents a difference (nxB-nyB) between nxB (refractive index in a slow axis direction) and nyB (refractive index in a fast, axis direction).

It is preferred that the nyA of the thermoplastic resin layer (A) and the nyB of the thermoplastic resin layer (B) be substantially equal to each other. The absolute value of a difference between the nyA and the nyB is preferably 5×10⁻² or less, more preferably 1×10⁻² or less, particularly preferably 0.5×10⁻² or less. The linearly polarized light separation-type brightness enhancement film having such optical characteristic is excellent in function of reflecting a polarized light component.

Any appropriate resin may be selected as a resin forming the thermoplastic resin layer (A). The thermoplastic resin layer (A) preferably contains a polyethylene terephthalate-based resin, a polytrimethylene terephthalate-based resin, a polybutylene terephthalate-based resin, a polyethylene naphthalate-based resin, or a polybutylene naphthalate-based resin, or a mixture thereof. Each of those resins is excellent in property of expressing birefringence through stretching, and is excellent in stability of the birefringence after the stretching.

Any appropriate resin may be selected as a resin forming the thermoplastic resin layer (B). The thermoplastic resin layer (B) preferably contains a polystyrene-based resin, a polymethyl methacrylate-based resin, or a polystyrene glycidyl methacrylate-based resin. In addition, a polyethylene terephthalate-based resin, a polytrimethylene terephthalate-based resin, a polybutylene terephthalate-based resin, a polyethylene naphthalate-based resin, a polybutylene naphthalate-based resin, or the like designed so that birefringence caused by stretching maybe small maybe used. The resins may be used alone or in combination thereof. In addition, a halogen group, such as chlorine, bromine, or iodine, may be introduced into each of the resins for improving its refractive index. Alternatively, each of the resins may contain any appropriate additive for adjusting the refractive index.

A commercial film may be used as it is as the linearly polarized light separation-type brightness enhancement film. Examples of the commercial brightness enhancement film include D-BEF series manufactured by Sumitomo 3M Limited.

B-2. Circularly Polarized Light Separation-type Brightness Enhancement Film

Any appropriate film may be used as a circularly polarized light separation-type brightness enhancement film as long as the film can separate and reflect circularly polarized light. The circularly polarized light separation-type brightness enhancement film includes, for example, a cholesteric liquid crystal film. In addition, the circularly polarized light separation-type brightness enhancement film may further include a λ/4 film for the purpose of transforming circularly polarized light into linearly polarized light.

The thickness of the circularly polarized light separation-type brightness enhancement film is preferably from 1 μm to 230 μm. When the circularly polarized light separation-type brightness enhancement film includes the λ/4 film, the thickness of the circularly polarized light separation-type brightness enhancement film is more preferably from 1.5 μm to 130 μm, still more preferably from 2 μm to 115 μm. When the circularly polarized light separation-type brightness enhancement film does not include the λ/4 film, the thickness of the circularly polarized light separation-type brightness enhancement film is more preferably from 1 μm to 40 μm, still more preferably from 2 μm to 20 μm, particularly preferably from 2 μm to 15 μm.

The cholesteric liquid crystal film includes a cholesteric liquid crystal polymer alignment layer, and has a characteristic of reflecting one of left-handed circularly polarized light and right-handed circularly polarized light, and transmitting the other light. The cholesteric liquid crystal polymer alignment layer may be formed of a cholesteric liquid crystal polymer having a constituent unit derived from an optically active group-containing monomer. The thickness of the cholesteric liquid crystal film is preferably from 1 pro to 30 μm, more preferably from 2 μm to 15 μm. The cholesteric liquid crystal film may be compounded with a polymer except the liquid crystal polymer, or one or more kinds of additives, such as inorganic compounds including a stabilizer and a plasticizer, organic compounds, and metals and compounds thereof, as required.

The circularly polarized light separation-type brightness enhancement film may include a plurality of cholesteric liquid crystal films. A plurality of cholesteric liquid crystal films having different reflection wavelengths are preferably used. The adoption of such construction enables the formation of a circularly polarized light separation-type brightness enhancement film from which transmitted circularly polarized light in a wide wavelength range can be obtained.

The λ/4 film means a retardation film having a function of transforming linearly polarized light having a specific wavelength into circularly polarized light (or circularly polarized light into linearly polarized light).

The in-plane retardation Re of the λ/4 film at a wavelength of 590 nm is preferably from 90 nm to 200 nm, more preferably from 110 nm to 180 nm, still more preferably from 120 nm to 170 nm. When the in-plane retardation Re falls within such range, the retardation film can function as a λ/4 plate. In this description, the in-plane retardation Re is determined from an equation “Re= (nx−ny)×d” where nx represents a refractive index in a direction in which a refractive index in a plane becomes maximum under 23° C. (i.e., a slow axis direction), ny represents a refractive index in a direction perpendicular to a slow axis in the plane (i.e., a fast axis direction), and d (nm) represents the thickness of the film. The λ/4 film shows any appropriate refractive index ellipsoid as long as the film has a relationship of nx>ny. For example, the refractive index ellipsoid of the retardation film shows a relationship of nx>nz>ny or of nx>ny≧nz.

The thickness of the λ/4 film is preferably from 0.5 μm to 200 μm, more preferably from 1 μm to 100 μm.

Examples of the λ/4 film include: a birefringent film obtained by stretching a film formed of any of polymers including polycarbonate, a norbornene-based resin, polyvinyl alcohol, polystyrene, polymethyl methacrylate, polyolefin-based resins, such as polypropylene, polyarylate, and polyamide; an alignment film formed of a liquid crystal material, such as a liquid crystal polymer; and a film including a liquid crystal material alignment layer.

In one embodiment, a retardation film is arranged between the cholesteric liquid crystal film and the λ/4 film. The retardation film is, for example, a homeotropic alignment film.

C. Resin Layer

The resin layer preferably contains a curable resin. Examples of the curable resin constituting the resin layer include an acrylic resin, an epoxy-based resin, and a silicone-based resin.

The resin layer may be formed by applying a composition for forming a resin layer onto the brightness enhancement film, and then curing the composition.

The composition for forming a resin layer preferably contains, as a curable compound serving as a main component, a polyfunctional monomer, an oligomer derived from a polyfunctional monomer, and/or a prepolymer derived from a polyfunctional monomer. Examples of the polyfunctional monomer include tricyclodecanemethanol diacrylate, pentaerythritol di(meth)acrylate, pentaerythritol tri(meth)acrylate, trimethylolpropane triacrylate, pentaerythritol tetra(meth)acrylate, dimethylolpropane tetraacrylate, dipentaerythritol hexa(meth)acrylate, 1,6-hexanediol (meth)acrylate, 1,9-nonanediol diacrylate, 1,10-decanediol (meth)acrylate, polyethylene glycol di(meth)acrylate, polypropylene glycol di(meth)acrylate, dipropylene glycol diacrylate, isocyanuric acid tri(meth)acrylate, ethoxylated glycerin triacrylate, and ethoxylated pentaerythritol tetraacrylate. The polyfunctional monomers may be used alone or in combination.

In one embodiment, the polyfunctional monomer has a hydroxyl group. The use of the composition for forming a resin layer containing the polyfunctional monomer having a hydroxyl group can provide a conductive sheet excellent in adhesiveness of the transparent conductive layer. Examples of the polyfunctional monomer having a hydroxyl group include pentaerythritol tri(meth)acrylate and dipentaerythritol pentaacrylate.

The content of the polyfunctional monomer, the oligomer derived from the polyfunctional monomer, and the prepolymer derived from the polyfunctional monomer is preferably from 30 parts by weight to 100 parts by weight, more preferably from 40 parts by weight to 95 parts by weight, particularly preferably from 50 parts by weight to 95 parts by weight with respect to 100 parts by weight of the total amount of the monomer, the oligomer, and the prepolymer in the composition for forming a resin layer. When the content falls within such range, the adhesiveness of the transparent conductive layer is improved, and hence a conductive sheet in which interlayer peeling hardly occurs can be obtained. In addition, the curing shrinkage of the resin layer can be effectively prevented.

The composition for forming a resin layer may contain a monofunctional monomer. When the composition for forming a resin layer contains the monofunctional monomer, the content of the monofunctional monomer is preferably 40 parts by weight or less, more preferably 20 parts by weight or less with respect to 100 parts by weight of the total amount of the monomers, the oligomer, and the prepolymer in the composition for forming a resin layer.

Examples of the monofunctional monomer include ethoxylated o-phenylphenol (meth)acrylate, methoxy polyethylene glycol (meth)acrylate, phenoxy polyethylene glycol (meth)acrylate, 2-ethylhexyl acrylate, lauryl acrylate, isooctyl acrylate, isostearyl acrylate, cyclohexyl acrylate, isobornyl acrylate, benzyl acrylate, 2-hydroxy-3-phenoxyacrylate, acryloylmorpholine, 2-hydroxyethyl (meth)acrylate, 4-hydroxybutyl (meth)acrylate, and hydroxyethylacrylamide. In one embodiment, a monomer having a hydroxyl group is used as the monofunctional monomer.

The composition for forming a resin layer may contain a urethane (meth)acrylate and/or an oligomer of the urethane (meth)acrylate. When the composition for forming a resin layer contains the urethane (meth)acrylate and/or the oligomer of the urethane (meth)acrylate, a resin layer excellent in flexibility and adhesiveness with the brightness enhancement film can be formed. The urethane (meth)acrylate may be obtained by, for example, subjecting a hydroxy (meth)acrylate obtained from (meth)acrylic acid or a (meth)acrylate and a polyol to a reaction with a diisocyanate. The urethane (meth)acrylates and oligomers of the urethane (meth)acrylates may be used alone or in combination.

Examples of the (meth)acrylate include methyl (meth)acrylate, ethyl (meth)acrylate, isopropyl (meth)acrylate, butyl (meth)acrylate, and cyclohexyl (meth)acrylate.

Examples of the polyol include ethylene glycol, 1,3-propylene glycol, 1,2-propylene glycol, diethylene glycol, dipropylene glycol, neopentyl glycol, 1,3-butanediol, 1,4-butanediol, 1,6-hexanediol, 1,9-nonanediol, 1,10-decanediol, 2,2,4-trimethyl-1,3-pentanediol, 3-methyl-1,5-pentanediol, neopentyl glycol hydroxypivalate, tricyclodecanedimethylol, 1,4-cyclohexanediol, spiroglycol, tricyclodecanedimethylol, hydrogenated bisphenol A, a bisphenol A-ethylene oxide adduct, a bisphenol A-propylene oxide adduct, trimethylolethane, trimethylolpropane, glycerin, 3-methylpentane-1,3,5-triol, pentaerythritol, dipentaerythritol, tripentaerythritol, and glucoses.

For example, various kinds of aromatic, aliphatic, and alicyclic diisocyanates may be used as the diisocyanate. Specific examples of the diisocyanate include tetramethylene diisocyanate, hexamethylene diisocyanate, isophorone diisocyanate, 2,4-tolylene diisocyanate, 4,4-diphenyl diisocyanate, 1,5-naphthalene diisocyanate, 3,3-dimethyl-4,4-diphenyl diisocyanate, xylene diisocyanate, trimethylhexamethylene diisocyanate, 4,4-diphenylmethane diisocyanate, and hydrogenated products thereof.

The total content of the urethane (meth)acrylate and the oligomer of the urethane (meth)acrylate is preferably from 5 parts by weight to 70 parts by weight, more preferably from 5 parts by weight to 50 parts by weight with respect to 100 parts by weight of the total amount of the monomer, oligomer, and prepolymer in the composition for forming a resin layer. When the total content falls within such range, a resin layer excellent in balance among hardness, flexibility, and adhesiveness can be formed.

The composition for forming a resin layer preferably contains any appropriate photopolymerization initiator.

The composition for forming a resin layer may or may not contain a solvent. Examples of the solvent include dibutyl ether, dimethoxymethane, methyl acetate, ethyl acetate, isobutyl acetate, methyl propionate, ethyl propionate, methanol, ethanol, and methyl isobutyl ketone (MIBK). Those solvents may be used alone or in combination.

The composition for forming a resin layer may further contain any appropriate additive. Examples of the additive include a leveling agent, an antiblocking agent, a dispersion stabilizer, a thixotropic agent, an antioxidant, a UV absorber, an antifoaming agent, a thickener, a dispersant, a surfactant, a catalyst, a filler, a lubricant, and an antistatic agent.

As a method of applying the composition for forming a resin layer, any appropriate method may be adopted. Examples of the method include a bar coating method, a roll coating method, a gravure coating method, a rod coating method, a slot orifice coating method, a curtain coating method, a fountain coating method, and a comma coating method.

Any appropriate curing treatment may be adopted as a method of curing the composition for forming a resin layer. The curing treatment is typically performed by ultraviolet irradiation. The integrated light quantity of the ultraviolet irradiation is preferably from 200 mJ/cm² to 1,000 mJ/cm².

Before the composition for forming a resin layer is cured, an applied layer formed of the composition for forming a resin layer may be heated. The heating can improve the adhesiveness between the brightness enhancement film and the resin layer. A heating temperature is preferably from 70° C. to 140° C., more preferably from 80° C. to 130° C.

The thickness of the resin layer is preferably from 0.5 μm to 50 μm, more preferably from 0.8 μm to 10 μm, still more preferably from 0.9 μm to 5 μm. When the thickness of the resin layer falls within such range, a conductive sheet in which the transparent conductive layer hardly peels and which is excellent in transparency can be obtained.

The tensile modulus of elasticity of the resin layer at 25° C. is preferably from 2.5 GPa to 20 GPa, more preferably from 3 GPa to 15 GPa, still more preferably from 3.5 GPa to 10 GPa. The tensile modulus of elasticity may be measured in conformity with JIS K 7161.

The linear thermal expansion coefficient of the resin layer at from 50° C. to 250° C. is preferably from 0/° C. to 100×10⁻⁶/° C., more preferably from 0/° C. to 50×10⁻⁶/° C.

D. Transparent Conductive Layer

Examples of the form of the transparent conductive layer include a transparent conductive layer containing metal nanowires, a transparent conductive layer containing a metal mesh, and a transparent conductive layer containing a conductive polymer.

The thickness of the transparent conductive layer may be set to any appropriate thickness in accordance with its form. From the viewpoint of light permeability, the thickness of the transparent conductive layer is preferably as small as possible as long as desired conductivity is obtained. The thickness of the transparent conductive layer is preferably 10 μm or less, more preferably 1 μm or less. The transparent conductive layer having such thickness can achieve both conductivity and a light transmittance at high levels.

The total light transmittance of the transparent conductive layer is preferably 85% or more, more preferably 90% or more, still more preferably 95% or more.

D-1. Transparent Conductive Layer Containing Metal Nanowires

The metal nanowires each refer to a conductive substance that uses a metal as a material, has a needle- or thread-like shape, and has a diameter of the order of nanometers. The metal nanowires may be linear or may be curved. When a transparent conductive layer including the metal nanowires is used, the metal nanowires are formed into a network shape. Accordingly, even when a small amount of the metal nanowires is used, a good electrical conduction path can be formed and hence a conductive sheet having a small electrical resistance can be obtained. Further, the metal nanowires are formed into a network shape, and hence an opening portion is formed in a gap of the network. As a result, a conductive sheet having a high light, transmittance can be obtained.

A ratio (aspect ratio: L/d) between a thickness d and length L of each of the metal nanowires is preferably from 10 to 100,000, more preferably from 50 to 100,000, particularly preferably from 100 to 10,000. When metal nanowires each having such large aspect ratio as described above are used, the metal nanowires satisfactorily intersect with each other and hence high conductivity can be expressed with a small amount of the metal nanowires. As a result, a conductive sheet having a high light transmittance can be obtained. The term “thickness of the metal nanowires” as used herein has the following meanings: when a section of each of the metal nanowires has a circular shape, the term means the diameter of the circle; when the section has an elliptical shape, the term means the short diameter of the ellipse; and when the section has a polygonal shape, the term means the longest diagonal of the polygon. The thickness and length of each of the metal nanowires may be observed with a scanning electron microscope or a transmission electron microscope.

The thickness of each of the metal nanowires is preferably less than 500 nm, more preferably less than 200 nm, particularly preferably from 10 nm to 100 nm, most preferably from 10 nm to 50 nm. When the thickness falls within such range, a transparent conductive layer having a high light transmittance can be formed.

The length of each of the metal nanowires is preferably from 1 μm to 1,000 μm, more preferably from 10 μm to 500 μm, particularly preferably from 20 μm to 100 μm. When the length falls within such range, a conductive sheet having high conductivity can be obtained.

Any appropriate metal may be used as a metal constituting the metal nanowires as long as the metal has high conductivity. Examples of the metal constituting the metal nanowires include silver, gold, copper, and nickel. In addition, a material obtained by subjecting any such metal to a plating treatment (such as a gold plating treatment) may be used. Of those, silver, copper, or gold is preferred from the viewpoint of conductivity, and silver is more preferred.

Any appropriate method may be adopted as a method of producing the metal nanowires. Examples thereof include: a method involving reducing silver nitrate in a solution; and a method involving causing an applied voltage or current to act on a precursor surface from the tip portion of a probe, drawing metal nanowires at the tip portion of the probe, and continuously forming the metal nanowires. In the method involving reducing silver nitrate in the solution, silver nanowires can be synthesized by performing liquid-phase reduction with a silver salt, such as silver nitrate, in the presence of a polyol, such as ethylene glycol, and polyvinyl pyrrolidone. The mass production of silver nanowires each having a uniform size can be performed in conformity with a method disclosed in, for example, Xia, Y. et al., Chem. Mater. (2002), 14, 4736-4745 or Xia, Y. et al., Nano letters (2003), 3 (7), 955-960.

The transparent conductive layer containing the metal nanowires may be formed by applying, onto the resin layer, a composition for forming a transparent conductive layer containing the metal nanowires. More specifically, the transparent conductive layer may be formed by applying, onto the resin layer, a dispersion liquid (composition for forming a transparent conductive layer) obtained by dispersing the metal nanowires in a solvent, and then drying the applied layer.

Examples of the solvent include water, an alcohol-based solvent, a ketone-based solvent, an ether-based solvent, a hydrocarbon-based solvent, and an aromatic solvent. Water is preferably used from the viewpoint of reduction in environmental load.

The dispersion concentration of the metal nanowires in the composition for forming a transparent conductive layer containing the metal nanowires is preferably from 0.1 wt % to 1 wt %. When the dispersion concentration falls within such range, a transparent conductive layer excellent in conductivity and light transmittance can be formed.

The composition for forming a transparent conductive layer containing the metal nanowires may further contain any appropriate additive depending on purposes. Examples of the additive include an anticorrosive material for preventing the corrosion of the metal nanowires and a surfactant for preventing the agglomeration of the metal nanowires. The kinds, number, and amount of additives to be used may be appropriately set depending on purposes. In addition, the composition for forming a transparent conductive layer may contain any appropriate binder resin as required as long as the effects of the present invention are obtained.

Any appropriate method may be adopted as an application method for the composition for forming a transparent conductive layer containing the metal nanowires. Examples of the application method include spray coating, bar coating, roll coating, die coating, inkjet coating, screen coating, dip coating, a relief printing method, an intaglio printing method, and a gravure printing method. Any appropriate drying method (such as natural drying, blast drying, or heat drying) may be adopted as a method of drying the applied layer. In the case of, for example, the heat drying, a drying temperature is typically from 100° C. to 200° C. and a drying time is typically from 1 minute to 10 minutes.

When the transparent conductive layer contains the metal nanowires, the thickness of the transparent conductive layer is preferably 10 μm or less, more preferably 4 μm or less, still more preferably 1 μm or less, still further more preferably 0.2 μm or less, particularly preferably 50 nm or less, most preferably 35 nm or less. When the thickness falls within such range, a conductive sheet excellent in light permeability can be obtained. When the transparent conductive layer contains the metal nanowires, a lower limit for the thickness of the transparent conductive layer is, for example, 10 nm.

The content of the metal nanowires in the transparent conductive layer is preferably from 80 wt % to 100 wt %, more preferably from 85 wt % to 99 wt % with respect to the total weight of the transparent conductive layer. When the content falls within such range, a conductive sheet excellent in conductivity and light transmittance can be obtained.

The transparent conductive layer containing the metal nanowires may further contain a binder resin. The binder resin can protect the metal nanowires.

The transparent conductive layer containing the binder resin may be formed of the composition for forming a transparent conductive layer (composition for forming a transparent conductive layer containing the metal nanowires) after the binder resin has been incorporated into the composition, or maybe formed by: applying and drying the composition for forming a transparent conductive layer containing the metal nanowires; and then further applying another composition for forming a transparent conductive layer (composition containing the binder resin or a binder resin precursor).

As the binder resin, any appropriate resin may be used. Examples of the resin include: acrylic resins; polyester-based resins, such as polyethylene terephthalate; aromatic resins, such as polystyrene, polyvinyltoluene, polyvinylxylene, polyimide, polyamide, and polyamide imide; polyurethane-based resins; epoxy-based resins; polyolefin-based resins; acrylonitrile-butadiene-styrene copolymers (ABS); cellulose; silicone-based resins; polyvinyl chloride; polyacetate; polynorbornene; synthetic rubbers; and fluorine-based resins. A curable resin (preferably UV-curable resin) formed of a poly functional acrylate, such as pentaerythritol triacrylate (PETA), neopentyl glycol diacrylate (NPGDA), dipentaerythritol hexaacrylate (DPHA), dipentaerythritol pentaacrylate (DPPA), or trimethylolpropane triacrylate (TMPTA), is preferably used.

D-2. Transparent Conductive Layer Containing Metal Mesh

The transparent conductive layer containing the metal mesh may be obtained by forming thin metal wires into a lattice pattern on the resin layer. The transparent conductive layer containing the metal mesh may be formed by any appropriate method. The transparent conductive layer may be obtained by, for example, applying a photosensitive composition (composition for forming a transparent conductive layer) containing a silver salt onto the resin layer, and then subjecting the resultant to an exposure treatment and a developing treatment to form the thin metal wires into a predetermined pattern. In addition, the transparent conductive layer may be obtained by printing a paste (composition for forming a transparent conductive layer) containing metal fine particles into a predetermined pattern. Details about such transparent conductive layer and a formation method therefor are disclosed in, for example, JP 2012-18634 A, and the disclosure is incorporated herein by reference. In addition, other examples of the transparent conductive layer including the metal mesh and the formation method therefor are a transparent conductive layer and formation method therefor disclosed in JP 2003-331654 A.

When the transparent conductive layer contains the metal mesh, the thickness of the transparent conductive layer is preferably 30 μm or less, more preferably 10 μm or less, still more preferably 3 μm or less, particularly preferably 500 nm or less, most preferably 300 nm or less. When the thickness falls within such range, a conductive sheet excellent in light permeability can be obtained. When the transparent conductive layer contains the metal mesh, a lower limit for the thickness of the transparent, conductive layer is, for example, 10 nm.

When the transparent conductive layer contains the metal mesh, the transmittance of the transparent conductive layer is preferably 80% or more, more preferably 85% or more, still more preferably 90% or more.

D-3. Transparent Conductive Layer Containing Conductive Polymer

The transparent conductive layer containing the conductive polymer may be formed by applying, onto the resin layer, a conductive composition containing the conductive polymer.

Examples of the conductive polymer include a polythiophene-based polymer, a polyacetylene-based polymer, a polyparaphenylene-based polymer, a polyaniline-based polymer, a polyparaphenylene vinylene-based polymer, a polypyrrole-based polymer, a polyphenylene-based polymer, and a polyester-based polymer modified with an acrylic polymer. The transparent conductive layer preferably contains one or more kinds of polymers selected from the group consisting of a polythiophene-based polymer, a polyacetylene-based polymer, a polyparaphenylene-based polymer, a polyaniline-based polymer, a polyparaphenylene vinylene-based polymer, and a polypyrrole-based polymer.

A polythiophene-based polymer is more preferably used as the conductive polymer. A transparent conductive layer excellent in transparency and chemical stability can be formed by using the polythiophene-based polymer. Specific examples of the

polythiophene-based polymer include: polythiophene; a poly(3-C₁₋₈alkyl-thiophene), such as poly(3-hexylthiophene); a poly(3,4-(cyclo)alkylenedioxythiophene), such as poly(3,4-ethylenedioxythiophene), poly(3,4-propylenedioxythiophene), or poly[3,4-(1,2-cyclohexylene)dioxythiophene]; and polythienylene vinylene.

The conductive polymer is preferably polymerized in the presence of an anionic polymer. For example, the polythiophene-based polymer is preferably oxidation-polymerized in the presence of the anionic polymer. Examples of the anionic polymer include polymers each having a carboxyl group, a sulfonic group, and/or a salt thereof. An anionic polymer having a sulfonic group, such as polystyrene sulfonic acid, is preferably used.

The conductive polymer, the transparent conductive layer including the conductive polymer, and a method of forming the transparent conductive layer are disclosed in, for example, JP 2011-175601 A, and the disclosure is incorporated herein by reference.

When the transparent conductive layer includes the conductive polymer, the thickness of the transparent conductive layer is preferably 1 μm or less, more preferably 0.5 μm or less, still more preferably 0.3 μm or less, particularly preferably 50 nm or less, most preferably 35 nm or less. When the thickness falls within such range, a conductive sheet excellent in light permeability can be obtained. When the transparent conductive layer contains the conductive polymer, a lower limit for the thickness of the transparent conductive layer is preferably 10 nm, more preferably 30 nm.

E. Optical Laminate

FIG. 2 is a schematic sectional view of an optical laminate according to one embodiment of the present invention. An optical laminate 200 illustrated in FIG. 2 includes the conductive sheet 100 and a polarizing plate 110. The conductive sheet 100 and the polarizing plate 110 are bonded to each other through intermediation of any appropriate adhesive or pressure-sensitive adhesive, though the adhesive or the pressure-sensitive adhesive is not shown. The conductive sheets described in the section A to the section D may each be used as the conductive sheet. Any appropriate polarizing plate may be used as the polarizing plate. The optical laminate of the present invention can be used as, for example, the back surface side polarizing plate of the liquid crystal cell of a liquid crystal display apparatus, and can contribute to the enhancement of the brightness of the liquid crystal display apparatus through the action of the brightness enhancement film included in the conductive sheet. In addition, the optical laminate of the present invention can express an electromagnetic shielding characteristic through the action of the transparent conductive layer included in the conductive sheet.

It is preferred that the polarizing plate 110 be arranged on the side of the conductive sheet 100 closer to the brightness enhancement film 10 (i.e., the side of the brightness enhancement film 10 opposite to the resin layer 20) like the illustrated example. When such arrangement is adopted, the polarized state of light that has been transmitted through the brightness enhancement film is easily maintained, and hence an optical laminate having a high brightness-enhancing effect can be obtained.

An angle formed between the polarized light transmission axis of the conductive sheet and the polarized light transmission axis of the polarizing plate is preferably 10° or less, more preferably 5° or less, still more preferably 1° or less. The angle formed between the polarized light transmission axis of the conductive sheet and the polarized light transmission axis of the polarizing plate is particularly preferably 0° (i.e., the axes are particularly preferably parallel to each other). When the angle formed between the polarized light transmission axis of the conductive sheet and the polarized light transmission axis of the polarizing plate falls within such range, the function of the brightness enhancement film is sufficiently exhibited.

### EXAMPLES

Now, the present invention is specifically described by way of Examples but the present invention is by no means limited by Examples described below. Evaluation methods in Examples are as described below. The thickness of a conductive sheet was measured as follows: the sheet was subjected to an embedding treatment with an epoxy resin, and then a section was formed by cutting the resultant with an ultramicrotome, followed by the measurement of the thickness of the section with a scanning electron microscope “S-4800” manufactured by Hitachi High-Technologies Corporation.

(1) Adhesiveness

Adhesiveness was identified by a crosscut method defined in JIS K 5400. Specifically, notches were made in a 10-millimeter square in the surface of the brightness enhancement film of a conductive sheet with a cutter at intervals of 1 mm so that 100 grids were produced. A pressure-sensitive adhesive tape was bonded onto the resultant, and was then peeled, followed by the evaluation of the adhesiveness on the basis of the number of grids that peeled from an inorganic glass. In Table 1, the case where the number of peeled grids is 10 or less is evaluated as ∘, and the case where the number of peeled grids is more than 10 is evaluated as ×.

(2) Measurement of Surface Resistance Value

The surface resistance value of a surface having formed thereon a transparent conductive layer was measured with a product available under the trade name “EC-80” from Napson Corporation by a noncontact eddy current method. The measurement was performed at an environmental temperature of 23° C.

(3) Measurement of Single Axis Transmittance and Polarization Degree

Polarized light transmission spectra k1 and k2 were measured with a spectrophotometer (manufactured by JASCO Corporation, product name: “V-7100”). Here, the k1 is a transmission spectrum when polarized light having an electric field vector parallel to the transmission axis of a polarizing film is caused to enter, and the k2 is a transmission spectrum when polarized light having an electric field vector perpendicular to the transmission axis of the polarizing film is caused to enter. A measurement wavelength was set to from 380 nm to 780 nm. A transmittance Y1 (transmittance for linearly polarized light in a maximum transmittance direction) and a transmittance Y2 (transmittance in a direction perpendicular to the maximum transmittance direction) subjected to visibility correction were determined from the spectra, and a single axis transmittance and a polarization degree were determined from the following equations.

Single axis transmittance=(Y1+Y2)/2

Polarization degree=(Y1−Y2)/(Y1+Y2)

(4) Measurement of Electromagnetic Shielding Characteristic

An electromagnetic shielding characteristic was measured by using a KEC method. A spectrum analyzer available under the trade name “N9010A” from Agilent Technologies was used, and a signal generator available under the trade name “N5183A” from Agilent Technologies was used. The measurement was performed at a frequency of 10 MHz.

### Example 1

(Preparation of Composition for forming Resin Layer)

25 Parts by weight of UV-curable urethane acrylate (manufactured by The Nippon Synthetic Chemical Industry Co., Ltd., trade name: “UV1700B”, weight-average molecular weight: about 2,000) serving as an acrylic hard coat resin, 25 parts by weight of a polyfunctional acrylate containing pentaerythritol triacrylate as a main component (manufactured by Osaka Organic Chemical Industry Ltd., trade name: “VISCOAT #300”), 1 part by weight of a photopolymerization initiator (manufactured by BASF, trade name: “IRGACURE 907”), 75 parts by weight of methyl isobutyl ketone, and 75 parts by weight of isopropyl alcohol were mixed to prepare a composition A for forming a resin layer.

(Preparation of Composition for forming Transparent Conductive Layer (Composition for forming Transparent Conductive Layer containing Silver Nanowires))

5 Milliliters of anhydrous ethylene glycol and 0.5 ml of a solution of PtCl₂ in anhydrous ethylene glycol (concentration: 1.5×10⁻⁴ mol/L) were added to a reaction vessel equipped with a stirring apparatus under 160° C. After a lapse of 4 minutes, 2.5 ml of a solution of AgNO₃ in anhydrous ethylene glycol (concentration: 0.12 mol/l) and 5 ml of a solution of polyvinyl pyrrolidone (MW: 55,000) in anhydrous ethylene glycol (concentration: 0.36 mol/l) were simultaneously dropped to the resultant solution over 6 minutes. After the dropping, the mixture was heated to 160° C. and a reaction was performed for 1 hour or more until AgNO₃ was completely reduced, to produce silver nanowires. Next, acetone was added to the reaction mixture containing the silver nanowires obtained as described above until the volume of the reaction mixture became 5 times as large as that before the addition. After that, the reaction mixture was centrifuged (2,000 rpm, 20 minutes). Thus, silver nanowires were obtained.

The resultant silver nanowires each had a short diameter of from 30 nm to 40 nm, a long diameter of from 30 nm to 50 nm, and a length of from 1 μm to 50 μm.

The silver nanowires (concentration: 0.2 wt %) and pentaethylene glycol dodecyl ether (concentration: 0.1 wt %) were dispersed in pure water to prepare a composition B1 for forming a transparent conductive layer containing the silver nanowires.

(Preparation of Composition for forming Transparent Conductive Layer (Composition for forming Transparent Conductive Layer Containing Binder Resin Precursor))

A solvent obtained by mixing isopropyl alcohol (manufactured by Wako Pure Chemical Industries, Ltd.) and diacetone alcohol (manufactured by Wako Pure Chemical Industries, Ltd.) at a weight ratio of 1:1 was used as a solvent. 3.0 Weight percent of dipentaerythritol hexaacrylate (DPHA) (manufactured by Shin-Nakamura Chemical Co., Ltd., trade name: “A-DPH”) and 0.09 wt % of a photoreaction initiator (manufactured by Ciba Japan, product name: “IRGACURE 907”) were loaded into the solvent. Thus, a composition B2 for forming a transparent conductive layer containing a binder resin precursor was prepared.

(Production of Laminate including Brightness Enhancement Film and Resin Layer)

A film available under the trade name “D-BEF” from Sumitomo 3M Limited (linearly polarized light separation-type brightness enhancement film, anisotropic multiple thin film, thickness: 20 μm) was used as a brightness enhancement film. The composition A for forming a resin layer was applied to the brightness enhancement film with a bar coater (manufactured by Dai-Ichi Rika, product name: “BAR COATER No. 10”), and was dried at 80° C. After that, the dried composition was irradiated with UV light having an integrated light quantity of 300 mJ/cm² by using a high-pressure mercury lamp. Thus, a laminate I in which a resin layer having a thickness of 2.5 μm was formed on the brightness enhancement film was obtained.

(Production of Conductive Sheet)

The composition B1 for forming a transparent conductive layer containing the silver nanowires was applied onto the resin layer of the laminate I with a bar coater (manufactured by Dai-Ichi Rika, product name: “BAR COATER No. 10”), and was dried in a fan dryer at 80° C. for 2 minutes. After that, the composition B2 for forming a transparent conductive layer containing the binder resin precursor was applied onto the resin layer with a slot die so that its thickness after drying became 0.2 μm, followed by drying in a fan dryer at 80° C. for 2 minutes. Next, a transparent conductive layer was formed by irradiating the composition B2 for forming a transparent conductive layer with UV light having an integrated illuminance of 400 mJ/cm² through the use of a UV light irradiation apparatus (manufactured by Fusion UV Systems), in which an environment having an oxygen concentration of 100 ppm had been established, to cure the composition. Thus, a conductive sheet (brightness enhancement film (20 μm)/resin layer (2.5 μm)/transparent conductive layer (0.2 μm)) was obtained.

The resultant conductive sheet was subjected to the evaluations (1) to (4). The results of the evaluations are shown in Table 1.

### Example 2

A laminate I (brightness enhancement film/resin layer) was obtained in the same manner as in Example 1.

A silver paste (manufactured by Toyochem Co., Ltd., trade name: “RA FS 039”) was applied onto the resin layer of the laminate I by a screen printing method to form a metal mesh (grids each having a line width of 10 μm and arranged at a pitch of 300 μm), and the metal mesh was sintered at 80° C. for 30 minutes. Thus, a conductive sheet, (brightness enhancement film (20 μm)/resin layer (2.5 μm)/transparent conductive layer (1.0 μm)) was obtained.

The resultant conductive sheet was subjected to the evaluations (1) to (4). The results of the evaluations are shown in Table 1.

### Example 3

A laminate I (brightness enhancement film/resin layer) was obtained in the same manner as in Example 1.

A PEDOT/PSS dispersion liquid serving as a composition for forming a transparent conductive layer (manufactured by Heraeus, trade name: “Clevios FE-T”; a dispersion liquid of a conductive polymer including polyethylene dioxythiophene and polystyrene sulfonic acid) was applied onto the resin layer of the laminate I, and was dried. Thus, a conductive sheet (brightness enhancement film (20 μm)/resin layer (2.5 μm)/transparent conductive layer (1.0 μm)) was obtained.

The resultant conductive sheet was subjected to the evaluations (1) to (4) . The results of the evaluations are shown in Table 1.

### Comparison Example 1

The composition B1 for forming a transparent conductive layer containing the silver nanowires was directly applied onto a brightness enhancement film (manufactured by Sumitomo 3M Limited, trade name: “D-BEF”), and was dried in a fan dryer at 80° C. for 2 minutes. After that, the composition B2 for forming a transparent conductive layer containing the binder resin precursor was applied onto the resultant with a slot die so that its thickness after drying became 0.2 μm, followed by drying in a fan dryer at 80° C. for 2 minutes, Next, a transparent conductive layer was formed by irradiating the composition B2 for forming a transparent conductive layer with UV light having an integrated illuminance of 400 mJ/cm² through the use of a UV light irradiation apparatus (manufactured by Fusion UV Systems), in which an environment having an oxygen concentration of 100 ppm had been established, to cure the composition. Thus, a conductive sheet (brightness enhancement film (20 μm)/transparent conductive layer (0.2 μm)) was obtained.

The resultant conductive sheet was subjected to the evaluations (1) to (4). The results of the evaluations are shown in Table 1.

TABLE 1

| | Surface | Single | | Electromagnetic | |
|---|---|---|---|---|---|
| | resistance | axis | Polarization | shielding | |
| | value | transmittance | degree | characteristic | |
| | (Ω/□) | (%) | (%) | (dB) | Adhesiveness |
| Example 1 | 166 | 47.3 | 90.9 | 37.4 | ∘ |
| Example 2 | 195 | 44.6 | 90.6 | 35.5 | ∘ |
| Example 3 | 93 | 42.8 | 90.6 | 41.1 | ∘ |
| Comparison | 164 | 47.2 | 90.9 | 37.0 | x |
| Example 1 | | | | | |

As is apparent from Table 1, according to the present invention, there can be obtained a conductive sheet which has satisfactory characteristics (a surface resistance value, a single axis transmittance, and a polarization degree) as a polarizing plate having an electromagnetic shielding function, and in which a conductive layer hardly peels.

### INDUSTRIAL APPLICABILITY

The conductive sheet of the present invention can be used in an electronic instrument, such as a display device.

### REFERENCE SIGNS LIST

10 brightness enhancement film
20 resin layer
30 transparent conductive layer
100 conductive sheet

1. A conductive sheet, comprising a brightness enhancement film, a resin layer, and a transparent conductive layer in the stated order.

2. The conductive sheet according to claim 1, wherein the transparent conductive layer contains metal nanowires.

3. The conductive sheet according to claim 2, wherein the metal nanowires comprise silver nanowires.

4. The conductive sheet according to claim 3, wherein the transparent conductive layer further contains a binder resin.

5. The conductive sheet according to claim 1, wherein the transparent conductive layer contains a metal mesh.

6. The conductive sheet according to claim 1, wherein the transparent conductive layer contains a conductive polymer.

7. The conductive sheet according to claim 1, wherein the brightness enhancement film comprises a linearly polarized light separation-type brightness enhancement film.

8. The conductive sheet according to claim 1, wherein the brightness enhancement film comprises a circularly polarized light separation-type brightness enhancement film.

9. The conductive sheet according to claim 1, wherein the resin layer contains an acrylic curable resin.

10. The conductive sheet according to claim 1, wherein the resin layer is directly formed on the brightness enhancement film, and the transparent conductive layer is directly formed on the resin layer.

11. The conductive sheet according to claim 1, wherein the conductive sheet has a single axis transmittance of from 30% to 70%.

12. The conductive sheet according to claim 1, wherein a surface of the conductive sheet on a transparent conductive layer side has a surface resistance value of from 10⁻² Ω/□ to 10⁴ Ω/□.

13. An optical laminate, comprising:
the conductive sheet of claim 1; and
a polarizing plate.

14. The optical laminate according to claim 13, wherein the polarizing plate is arranged on a brightness enhancement film side of the conductive sheet.

15. The optical laminate according to claim 13, wherein a polarized light transmission axis of the conductive sheet and a polarized light transmission axis of the polarizing plate are parallel to each other.
